(19) United States
(12) Patent Application Publication
(10) Pub. No.: US 2025/0155810 A1
(43) Pub. Date: May 15, 2025

(54) PHOTOSENSITIVE POLYMER, PHOTORESIST COMPOSITION INCLUDING THE SAME, AND METHOD OF MANUFACTURING SEMICONDUCTOR DEVICE

(71) Applicant: Samsung Electronics Co., Ltd., Suwon-si (KR)

(72) Inventors: Jiyup KIM, Suwon-si (KR); Beomgoo KANG, Seoul-si (KR); Songse YI, Suwon-si (KR); Dabin KIM, Seoul-si (KR); Woojae JANG, Seoul-si (KR)

(73) Assignees: Samsung Electronics Co., Ltd., Suwon-si (KR); Foundation of Soongsil University-Industry Cooperation, Seoul (KR)

(21) Appl. No.: 18/929,891

(22) Filed: Oct. 29, 2024

(30) Foreign Application Priority Data
Nov. 14, 2023 (KR) 10-2023-0157695

(51) Int. Cl. G03F 7/039; C08F 212/14; G03F 7/00; G03F 7/20; H01L 21/027

(52) U.S. Cl. CPC G03F 7/0392; C08F 212/24; G03F 7/2004; G03F 7/70033; H01L 21/0274

(57) ABSTRACT

A photosensitive polymer may include repeating units represented by Formula 1 and may have a polydispersity index (PDI) of 1.1 or less.

In Formula 1, R¹, R², R³, R⁴, R⁵, R⁶, R⁷, and R⁸ each independently may be a hydrogen atom, a C1-C3 linear or branched alkyl group, a substituted or unsubstituted C2-C3 linear or branched alkenyl group, a substituted or unsubstituted C2-C3 linear or branched alkynyl group, a substituted or unsubstituted C1-C3 alkoxy group, or a halogen element; A may be an acid-labile group having an acid desorption rate lower than that of a trialkylsilyl group; and m and n each may be an integer of 1 or more.

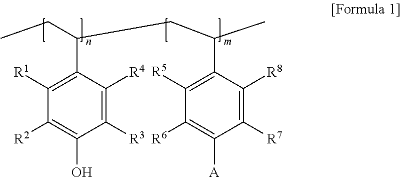

### CROSS-REFERENCE TO RELATED APPLICATION

This application is based on and claims priority under 35 U.S.C. § 119 to Korean Patent Application No. 10-2023-0157695, filed on Nov. 14, 2023, in the Korean Intellectual Property Office, the disclosure of which is incorporated by reference herein in its entirety.

### BACKGROUND

Inventive concepts relate to a photosensitive polymer, a photoresist composition including the photosensitive polymer, and a method of manufacturing a semiconductor device, and more particularly, to a photosensitive polymer including a narrowly dispersible copolymer formed by anionic polymerization, a photoresist composition including the photosensitive polymer, and a method of manufacturing a semiconductor device.

Due to the advance in electronics technology, semiconductor devices have been rapidly down-scaled in recent years. Therefore, photolithography processes for implementing fine patterns are required. In particular, it is required to develop photosensitive polymers and photoresist compositions capable of improving the dimensional precision of patterns in photolithography processes for manufacturing semiconductor devices.

### SUMMARY

Inventive concepts provide a photosensitive polymer, which allows a photoresist pattern having improved line-width roughness (LWR) and line-edge roughness (LER) to be obtained, and a photoresist composition including the photosensitive polymer.

Inventive concepts also provide a method of manufacturing a semiconductor device, the method allowing the dimensional precision of a pattern to be improved by forming a photoresist pattern having improved LWR and LER in a photolithography process.

According to an embodiment of inventive concepts, a photosensitive polymer may include repeating units represented by Formula 1. The photosensitive polymer may have a polydispersity index (PDI) of 1.1 or less.

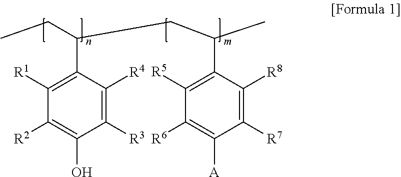

In Formula 1, R¹, R², R³, R⁴, R⁵, R⁶, R⁷ and R⁸ each independently may be a hydrogen atom, a C1-C3 linear or branched alkyl group, a substituted or unsubstituted C2-C3 linear or branched alkenyl group, a substituted or unsubstituted C2-C3 linear or branched alkynyl group, a substituted or unsubstituted C1-C3 alkoxy group, or a halogen element. Also, A may be an acid-labile group having an acid desorption rate which is lower than that of a trialkylsilyl group, and m and n each may be an integer of 1 or more.

The photosensitive polymer may be obtained by anionic polymerization of p-hydroxystyrene, in which a hydrogen atom of a hydroxyl group is substituted with a trialkylsilyl group; and p-styrene, in which a hydrogen atom is substituted with an acid-labile group.

According to an embodiment of inventive concepts, a photoresist composition may include a photosensitive polymer including repeating units represented by Formula 1, a photoacid generator (PAG), and a solvent. The photosensitive polymer may be obtained by anionic polymerization of p-hydroxystyrene, in which a hydrogen atom of a hydroxyl group is substituted with a trialkylsilyl group; and p-styrene, in which a hydrogen atom is substituted with an acid-labile group. The photosensitive polymer may have a polydispersity index (PDI) of 1.1 or less.

According to an embodiment of inventive concepts, a method of manufacturing a semiconductor device may include forming a photoresist film on a feature layer by using a photoresist composition, a photoacid generator (PAG), and a solvent; exposing a first region to light, the first region being a portion of the photoresist film, the exposing the first region to light forming an exposed region of the photoresist film and a non-exposed region of the photoresist film; forming a photoresist pattern by removing the exposed region of the photoresist film using a developer, the photoresist pattern including a non-exposed region of the photoresist film; and processing the feature layer using the photoresist pattern. The photoresist composition may include a photosensitive polymer including repeating units represented by Formula 1. The photosensitive polymer may have a polydispersity index (PDI) of 1.1 or less. The photosensitive polymer may be obtained by anionic polymerization of p-hydroxystyrene, in which a hydrogen atom of a hydroxyl group is substituted with a trialkylsilyl group; and p-styrene, in which a hydrogen atom is substituted with an acid-labile group.

### BRIEF DESCRIPTION OF THE DRAWINGS

Embodiments will be more clearly understood from the following detailed description taken in conjunction with the accompanying drawings in which:

FIG. 1 is a flowchart illustrating a method of preparing a photosensitive polymer, according to some embodiments;

FIG. 2 is a flowchart illustrating a method of manufacturing a semiconductor device, according to some embodiments; and

FIGS. 3 to 7 are cross-sectional views respectively illustrating processes of a method of manufacturing a semiconductor device, according to some embodiments.

### DETAILED DESCRIPTION

Hereinafter, embodiments of inventive concepts will be described in detail with reference to the accompanying drawings. Like components are denoted by like reference numerals throughout the specification, and repeated descriptions thereof are omitted.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

A photosensitive polymer according to some embodiments may include repeating units represented by Formula 1. The photosensitive polymer may be obtained by anionic polymerization of p-hydroxystyrene, in which a hydrogen atom of a hydroxyl group is substituted with a trialkylsilyl group, and p-styrene, in which a hydrogen atom is substituted with an acid-labile group. The photosensitive polymer may have a polydispersity index (PDI) of 1.1 or less.

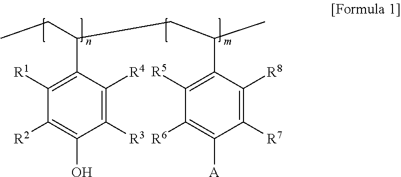

In Formula 1, R¹, R², R³, R⁴, R⁵, R⁶, R⁷ and R⁸ are each independently a hydrogen atom, a C1-C3 linear or branched alkyl group, a substituted or unsubstituted C2-C3 linear or branched alkenyl group, a substituted or unsubstituted C2-C3 linear or branched alkynyl group, a substituted or unsubstituted C1-C3 alkoxy group, or a halogen element,
A is an acid-labile group having an acid desorption rate which is lower than that of a trialkylsilyl group, and
m and n are each an integer of 1 or more.

In some embodiments, the acid-labile group may include an acid-labile group having a tertiary carbon atom.

In some embodiments, the acid-labile group may include an alkoxy group in which a tertiary carbon atom is directly bonded to an oxygen atom.

In some embodiments, the acid-labile group may have one structure selected from a group having the following structures.

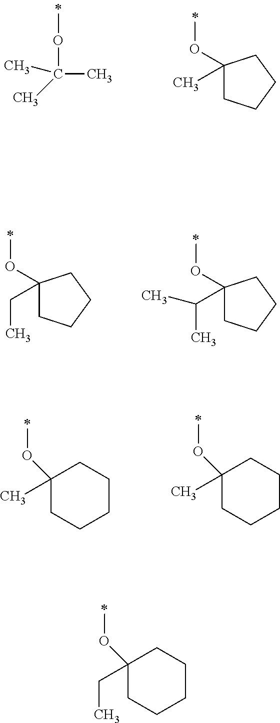

In the above structures, * represents a binding site.

In some embodiments, the acid-labile group may include an ester group in which a tertiary carbon atom is directly bonded to an oxygen atom.

In some embodiments, the acid-labile group may have one structure selected from a group having the following structures.

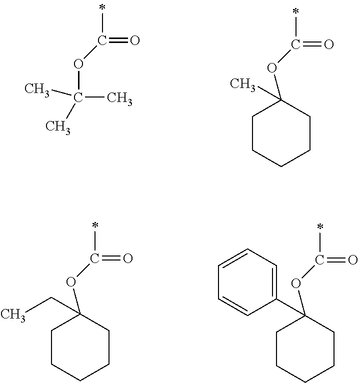

In the above structures, * represents a binding site.

A general photosensitive polymer formed by a radical polymerization reaction has a PDI of about 1.2 or more. As a result, there is a limit in improving the line edge roughness (LER) and line width roughness (LWR) of a pattern obtained from a photoresist film that is obtained from a photoresist composition including the photosensitive polymer, and thus, it may be difficult to achieve high pattern fidelity.

The photosensitive polymer according to some embodiments includes the repeating units represented by Formula 1 and has a PDI of about 1.1 or less. Because the photosensitive polymer according to some embodiments has a PDI that is lower than that of a general photosensitive polymer, a pattern obtained from a photoresist film that is obtained from a photoresist composition including the photosensitive polymer according to some embodiments may have improved LER and LWR, and thus, high pattern fidelity may be achieved.

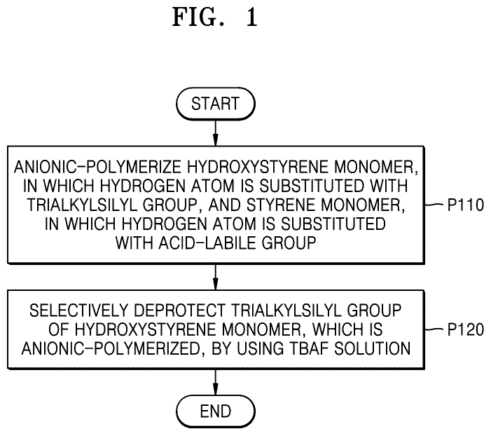

FIG. 1 is a flowchart illustrating a method of preparing a photosensitive polymer, according to some embodiments.

Referring to FIG. 1, a p-hydroxystyrene monomer (hereinafter, referred to as a monomer A), in which a hydrogen atom is substituted with a trialkylsilyl group, and a p-styrene monomer (hereinafter, referred to as a monomer C), in which a hydrogen atom is substituted with an acid-labile group, may be anionic-polymerized by using a polymerization initiator (P110).

In some embodiments, the trialkylsilyl group may include, but is not limited to, a trimethylsilyl group.

In some embodiments, the acid-labile group may have an acid desorption rate that is lower than the acid desorption rate of the trialkylsilyl group. For example, the trialkylsilyl group may include a trimethylsilyl group and the acid-labile group may include a tert-butoxy group having an acid desorption rate which is lower than that of the trialkylsilyl group.

In some embodiments, the polymerization initiator may include, but is not limited to, a sec-butyllithium.

Next, a trialkylsilyl group of a copolymer (that is, poly (A—r—C)) formed by process P110 may be selectively deprotected by using a tetra-butylammonium fluoride (TBAF) solution (P120).

As described above, the acid-labile group of the monomer C may have an acid desorption rate that is lower than the acid desorption rate of the trialkylsilyl group of the monomer A. Therefore, in process P120, only the trialkylsilyl group of the monomer A, which has a higher acid desorption rate, may be selectively deprotected by the TBAF solution. Because only the trialkylsilyl group of the monomer A is deprotected, a photosensitive polymer including a copolymer obtained by copolymerizing the hydroxystyrene monomer with the p-styrene monomer (that is, the monomer C), in which a hydrogen atom is substituted with an acid-labile group, may be formed. In addition, the selective deprotection process (that is, P120) is performed after the anionic polymerization process (that is, P110) rather than radical polymerization, thereby forming the photosensitive polymer having a PDI of about 1.1 or less and including the copolymer obtained by copolymerizing the hydroxystyrene monomer with the p-styrene monomer (that is, the monomer C), in which a hydrogen atom is substituted with an acid-labile group.

Hereinafter, a synthesis example of the photosensitive polymer according to some embodiments is described. The following synthesis example is illustrated for helping the understanding of the method of preparing a photosensitive polymer, according to some embodiments, and inventive concepts are not limited to the following synthesis example.

### Synthesis Example

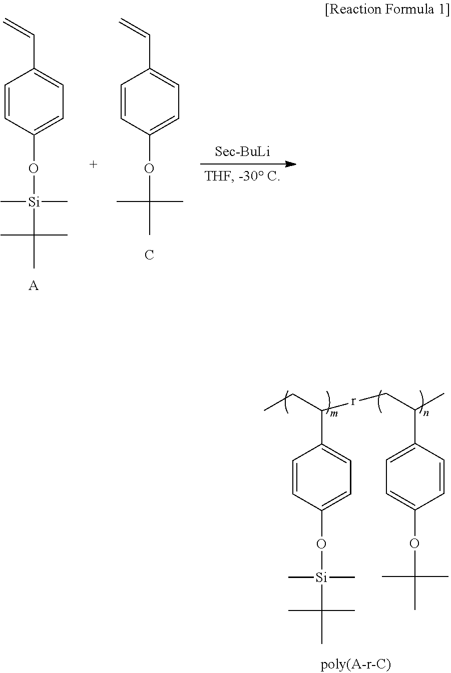

An anionic polymerization process according to Reaction Formula 1 was performed. To describe the process of Reaction Formula 1 in detail, the monomer A (1.3 mmol in 5 mL of tetrahydrofuran (THF)) and the monomer C (0.7 mmol in 3 mL of THF) were dissolved in an anhydrous THF solvent in an Ar atmosphere, followed by performing a reaction at −30° C. for 10 minutes by using sec-butyllithium as a polymerization initiator. Next, the reaction was terminated by introducing a small amount of methanol into the components set forth above, followed by precipitating an obtained reaction result product in an excess amount of methanol, thereby synthesizing a copolymer (poly(A—r—C)).

Table 1 shown below shows material properties of each of the copolymers (poly(A—r—C)) obtained depending on varying concentrations of the polymerization initiator, when the anionic polymerization process according to Reaction Formula 1 described above was performed with the varying concentrations of the polymerization initiator (sec-butyllithium).

TABLE 1

| | A | C | sec-BuL [symbol] | time | M [symbol] (kg/mol) | | | mol % of | wt % of |
|---|---|---|---|---|---|---|---|---|---|
| polymer | (mmol) | (mmol) | (mmol) | [symbol] min) | calcd [symbol] | [symbol] bsd [symbol] | M_{w}/Mₙ^{b} | poly(A) [symbol] | poly(A) [symbol] |
| poly(A-r-C)1 | 1.3 | 0.7 | 0.084 | 10 | 5.1 | 7.5 | 1.08 | 63 | 69 |
| poly(A-r-C)2 | 1.3 | 0.7 | 0.070 | 10 | 6.1 | 8.7 | 1.08 | 63 | 69 |
| poly(A-r-C)3 | 1.3 | 0.7 | 0.056 | 10 | 7.6 | 9.7 | 1.08 | 66 | 72 |

[symbol]

indicates data missing or illegible when filed

Referring to Table 1, when the anionic polymerization process according to Reaction Formula 1 was performed with the varying concentrations of sec-butyllithium, it may be confirmed that the copolymers (poly(A—r—C)) each having a PDI (M_{w}/Mₙ^{b}) of 1.08 were obtained.

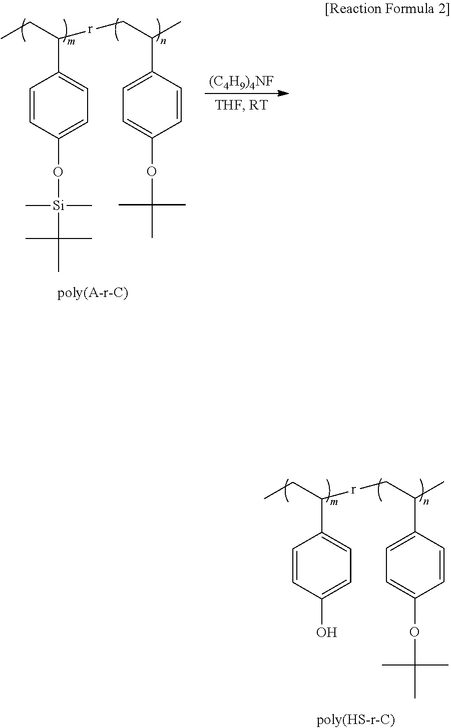

A selective deprotection process according to Reaction Formula 2 was performed. To describe the process of Reaction Formula 2 in detail, 0.5 g of the copolymer (poly(A—r—C)) synthesized by Reaction Formula 1 was dissolved in 20 mL of a THF solvent in an Ar atmosphere, followed by adding a TBAF solution (5 mmol in 5 mL of THF) to the components set forth above, and then, a reaction was performed at room temperature for 4 hours. Next, a reaction result product was concentrated, followed by precipitating the concentrated reaction result product twice in deionized water, thereby obtaining a copolymer, poly(HS—r—C), (0.17 g, yield 51%).

Table 2 shown below shows material properties of each of the copolymers (poly(HS—r—C)) obtained by performing the selective deprotection process according to Reaction Formula 2on each of the copolymers (poly(A—r—C)) that were obtained by performing the anionic polymerization process according to Reaction Formula 1 described above with the varying concentrations of the polymerization initiator (sec-butyllithium).

TABLE 2

| | M [symbol] (kg/mol) | | | mol % of | wt % of | weight |
|---|---|---|---|---|---|---|
| polymer | calcd [symbol] | [symbol] bsd [symbol] | M_{w}/Mₙ [symbol] | poly(HS) [symbol] | poly(HS) [symbol] | (g) |
| poly(HS-r-C)1 | 4.6 | 5.3 | 1.11 | 63.3 | 53.7 | 0.25 |
| poly(HS-r-C)2 | 5.5 | 7.6 | 1.09 | 63.3 | 53.7 | 0.17 |
| poly(HS-r-C)3 | 6.9 | 7.5 | 1.10 | 61.7 | 52.3 | 0.14 |

[symbol]

indicates data missing or illegible when filed

Referring to Table 2, when the selective deprotection process according to Reaction Formula 2 was performed on each of the copolymers (poly(HS—r—C)) obtained by performing the anionic polymerization process according to Reaction Formula 1, it may be confirmed that the copolymers (poly(HS—r—C)) having PDIs (M_{w}/Mₙ^{b}) of about 1.09 to about 1.11 were obtained. Therefore, it may be confirmed that the copolymers, poly (HS-r-C), obtained by performing the anionic polymerization process according to Reaction Formula 1 and the selective deprotection process according to Reaction Formula 2 have an average PDI of about 1.1.

A photoresist composition according to some embodiments may include a photosensitive polymer, a photoacid generator (PAG), and a solvent, the photosensitive polymer including the repeating units represented by Formula 1.

A more detailed description of the photosensitive polymer including the repeating units represented by Formula 1 is the same as described above.

In the photoresist composition according to some embodiments, the photosensitive polymer may be present in an amount of about 1 wt % to about 60 wt % based on the total weight of the photoresist composition, but embodiments of inventive concepts are not limited thereto.

The PGA of the photoresist composition according to some embodiments may generate an acid when exposed to light of one selected from a KrF excimer laser (248 nm), an ArF excimer laser (193 nm), an F2 excimer laser (157 nm), and an extreme ultraviolet (EUV) laser (13.5 nm). The PAG may include a material generating a relatively strong acid having an acid dissociation constant (pKa) of at least about −20 and less than about 1 due to light-exposure.

In some embodiments, the PAG may include triarylsulfonium salts, diaryliodonium salts, sulfonates, or mixtures thereof. For example, the PAG may include triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonate, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, or a mixture thereof.

In the photoresist composition according to some embodiments, the solvent may be present in an amount of about 0.1 wt % to about 5.0 wt % based on the total weight of the photosensitive polymer, but embodiments of inventive concepts are not limited thereto.

In the photoresist composition according to some embodiments, the solvent may include an organic solvent. In some embodiments, the solvent may include at least one of ethers, alcohols, glycol ethers, aromatic hydrocarbon compounds, ketones, and esters. For example, the solvent may be selected from ethylene glycol monomethyl ether, ethylene glycol monoethyl ether, methyl cellosolve acetate, ethyl cellosolve acetate, diethylene glycol monomethyl ether, diethylene glycol monocthyl ether, propylene glycol, propylene glycol monomethyl ether, propylene glycol monomethyl ether acetate, propylene glycol monoethyl ether, propylene glycol monocthyl ether acetate, propylene glycol propyl ether acetate, propylene glycol monobutyl ether, propylene glycol monobutyl ether acetate, toluene, xylene, methyl ethyl ketone, cyclopentanone, cyclohexanonc, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, and butyl lactate. These solvents may be used alone or in combination of at least two thereof. In some embodiments, the amount of the solvent in the photoresist composition may be adjusted such that solids are present in an amount of about 3 wt % to about 20 wt % in the photoresist composition.

In some embodiments, the photoresist composition may further include a basic quencher.

The basic quencher may trap an acid in a non-exposed region of a photoresist film, when the acid generated from the PAG of the photoresist composition according to some embodiments diffuses into the non-exposed region. The basic quencher may be included in the photoresist composition according to some embodiments, thereby preventing an issue generated due to the diffusion of an acid generated in an exposed region of a photoresist film, which is obtained from the photoresist composition, into a non-exposed region of the photoresist film after the photoresist film is exposed to light.

In some embodiments, the basic quencher may include primary aliphatic amines, secondary aliphatic amines, tertiary aliphatic amines, aromatic amines, heteroaromatic ring-containing amines, nitrogen-containing compounds having carboxyl groups, nitrogen-containing compounds having sulfonyl groups, nitrogen-containing compounds having hydroxyl groups, nitrogen-containing compounds having hydroxyphenyl groups, alcoholic nitrogen-containing compounds, amides, imides, carbamates, or ammonium salts. For example, the basic quencher may include, but is not limited to, triethanol amine, tricthyl amine, tributyl amine, tripropyl amine, hexamethyl disilazan, aniline, N-methylaniline, N-ethylaniline, N-propylaniline, N,N-dimethylaniline, N,N-bis (hydroxyethyl) aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or a combination thereof.

In some embodiments, the basic quencher may include a photo-decomposable base. The photo-decomposable base may include a compound generating an acid due to light-exposure and neutralizing an acid before light-exposure. When the photo-decomposable base is decomposed by light-exposure, the photo-decomposable base may lose a function of trapping an acid. Therefore, when a certain region of a photoresist film formed from the photoresist composition, which includes the basic quencher including the photo-decomposable base, is exposed to light, the photo-decomposable base may lose alkalinity in an exposed region of the photoresist film and may trap an acid in a non-exposed region of the photoresist film, thereby preventing an issue generated because acids generated in the exposed region of the photoresist film diffuse into the non-exposed region of the photoresist film.

The photo-decomposable base may include a carboxylate or sulfonate salt of a photo-decomposable cation. For example, the photo-decomposable cation may form a complex with an anion of a C1-C20 carboxylic acid. The carboxylic acid may include, but is not limited to, for example, formic acid, acetic acid, propionic acid, tartaric acid, succinic acid, cyclohexylcarboxylic acid, benzoic acid, or salicylic acid.

In the photoresist composition according to some embodiments, the basic quencher may be present in an amount of about 0.01 wt % to about 5.0 wt % based on the total weight of the photosensitive polymer, but embodiments of inventive concepts are not limited thereto.

In the photoresist composition according to some embodiments, the solvent may be present in the balance amount except for amounts of main components including the photosensitive polymer and the PAG. In some embodiments, the solvent may be present in an amount of about 0.1 wt % to about 99.7 wt % based on the total weight of the photoresist composition.

In some embodiments, the photoresist composition according to some embodiments may further include at least one selected from a surfactant, a dispersant, and a coupling agent.

The surfactant may improve the coating uniformity and wettability of the photoresist composition. In some embodiments, the surfactant may include, but is not limited to, a sulfuric acid ester salt, a sulfonic acid salt, phosphoric acid ester, soap, an amine salt, a quaternary ammonium salt, polyethylene glycol, an alkylphenol ethylene oxide adduct, a polyhydric alcohol, a nitrogen-containing vinyl polymer, or a combination thereof. For example, the surfactant may include an alkylbenzene sulfonate, an alkyl pyridinium salt, polyethylene glycol, or a quaternary ammonium salt. When the photoresist composition includes the surfactant, the surfactant may be present in an amount of about 0.001 wt % to about 3 wt % based on the total weight of the photoresist composition.

The dispersant may cause the respective components constituting the photoresist composition to be uniformly dispersed in the photoresist composition. In some embodiments, the dispersant may include, but is not limited to, an epoxy resin, polyvinyl alcohol, polyvinyl butyral, polyvinylpyrrolidone, glucose, sodium dodecyl sulfate, sodium citrate, oleic acid, linoleic acid, or a combination thereof. When the photoresist composition includes the dispersant, the dispersant may be present in an amount of about 0.001 wt % to about 5 wt % based on the total weight of the photoresist composition.

The coupling agent may improve adhesion to a lower film when the photoresist composition is coated on the lower film. In some embodiments, the coupling agent may include a silane coupling agent. The silane coupling agent may include, but is not limited to, vinyltrimethoxysilane, vinyltricthoxysilane, vinyltrichlorosilane, vinyltris (β-methoxyethoxy)silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldiethoxysilane, or trimethoxy[3-(phenylamino)propyl]silane. When the photoresist composition includes the coupling agent, the coupling agent may be present in an amount of about 0.001 wt % to about 5 wt % based on the total weight of the photoresist composition.

In the photoresist composition according to some embodiments, when the solvent includes only an organic solvent, the photoresist composition may further include water. In this case, water may be present in an amount of about 0.001 wt % to about 0.1 wt % in the photoresist composition.

In some embodiments, the photoresist composition may include a photoresist composition for EUV photolithography.

The photoresist composition include the repeating units represented by Formula 1, and the photosensitive polymer has a PDI of about 1.1 or less. Because the photosensitive polymer has a PDI that is lower than that of a general photosensitive polymer, a pattern obtained from a photoresist film that is obtained from the photoresist composition including the photosensitive polymer according to some embodiments may have improved LER and LWR, and thus, high pattern fidelity may be achieved.

Therefore, when a photolithography process for manufacturing a semiconductor device is performed by using the photoresist composition according to some embodiments, the LER and LWR of a pattern obtained from a photoresist film, which is obtained from the photoresist composition, may improve. Therefore, by manufacturing a semiconductor device by using the photoresist composition according to some embodiments, the dimensional precision of a pattern required for the semiconductor device may improve and the productivity of a manufacturing process of the semiconductor device may improve.

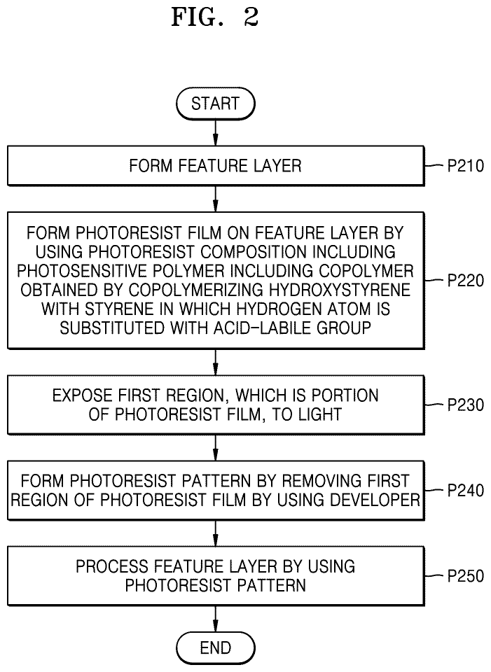

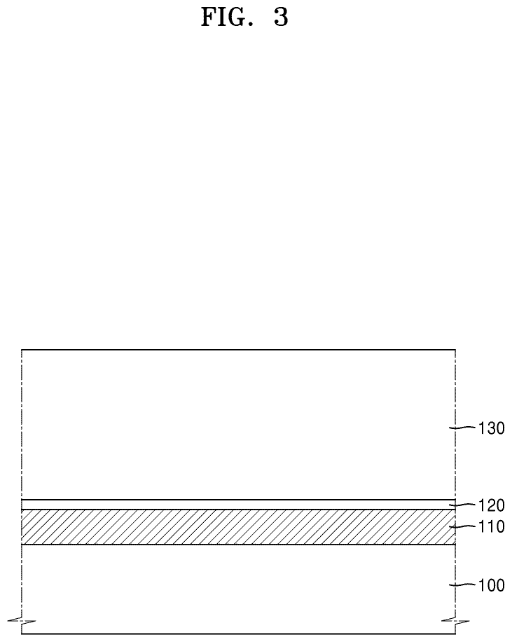

FIG. 2 is a flowchart illustrating a method of manufacturing a semiconductor device, according to some embodiments. FIGS. 3 to 7 are cross-sectional views respectively illustrating processes of a method of manufacturing a semiconductor device, according to some embodiments.

Referring to FIGS. 2 and 3, a feature layer 110 may be formed on a substrate 100 (P210), and a photoresist film 130 may be formed on the feature layer 110 by using the photoresist composition according to some embodiments.

The photoresist film 130 may include the photoresist composition including a photosensitive polymer, which includes the repeating units represented by Formula 1 and has a PDI of about 1.1 or less. Regarding a detailed configuration of Formula 1, a reference may be made to the description given above. A more detailed configuration of the photoresist composition is the same as described above.

The substrate 100 may include a semiconductor substrate. For example, the substrate 100 may include an elemental semiconductor material, such as Si or Ge, or a compound semiconductor material, such as SiGe, SiC, GaAs, InAs, or InP.

The feature layer 110 may include an insulating film, a conductive film, or a semiconductor film. For example, the feature layer 110 may include, but is not limited to, a metal, an alloy, a metal carbide, a metal nitride, a metal oxynitride, a metal oxycarbide, a semiconductor, polysilicon, an oxide, a nitride, an oxynitride, or a combination thereof.

In some embodiments, as shown in FIG. 3, before the photoresist film 130 is formed on the feature layer 110, a lower film 120 may be formed on the feature layer 110. In this case, the photoresist film 130 may be formed on the lower film 120. The lower film 120 may control the diffuse reflection of light from a light source used in an exposure process for manufacturing a semiconductor device or may absorb light reflected by the feature layer 110 under the lower film 120. In some embodiments, the lower film 120 may include an organic or inorganic anti-reflective coating (ARC) material for KrF excimer lasers, ArF excimer lasers, EUV lasers, or any other light sources. In some embodiments, the lower film 120 may include a bottom anti-reflective coating (BARC) film or a developable bottom anti-reflective coating (DBARC) film. In some embodiments, the lower film 120 may include an organic component having a light absorption structure. The light absorption structure may include, for example, a hydrocarbon compound having a structure in which one or more benzene rings are fused. The lower film 120 may have, but is not limited to, a thickness of about 20 nm to about 100 nm. In some embodiments, the lower film 120 may be omitted.

To form the photoresist film 130, the photoresist composition according to some embodiments may be coated on the lower film 120 and then heat-treated. The coating set forth above may be performed by a method, such as spin coating, spray coating, dip coating, or the like. A process of heat-treating the photoresist composition may be performed at a temperature of about 80° C. to about 300° C. for about 10 seconds to about 100 seconds, but embodiments of inventive concepts are not limited thereto. The thickness of the photoresist film 130 may be tens to hundreds of times the thickness of the lower film 120. The photoresist film 130 may have, but is not limited to, a thickness of about 100 nm to about 6 μm.

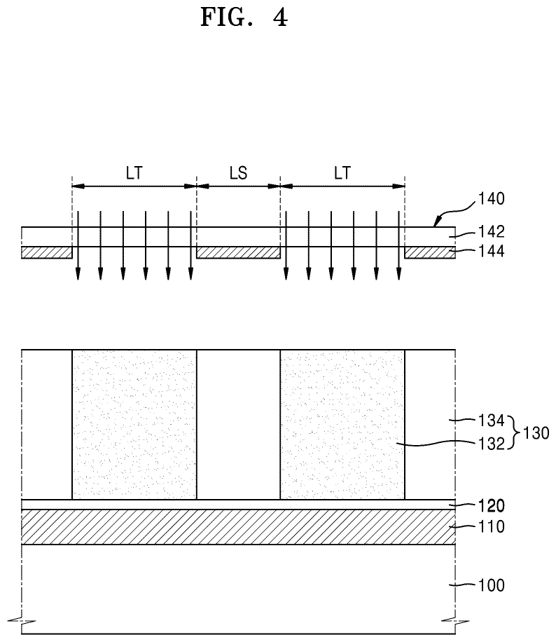

Referring to FIGS. 2 and 4, a first region 132, which is a portion of the photoresist film 130, may be exposed to light (P230).

In some embodiments, to expose the first region 132 of the photoresist film 130 to light, a photomask 140, which has a plurality of light shielding areas LS and a plurality of light transmitting areas LT, may be aligned at a certain position over the photoresist film 130, and the first region 132 of the photoresist film 130 may be exposed to light through the plurality of light transmitting areas LT of the photomask 140. In some embodiments, to expose the first region 132 of the photoresist film 130, an EUV laser (13.5 nm) may be used.

The photomask 140 may include a transparent substrate 142, and a plurality of light shielding patterns 144 formed on the transparent substrate 142 in the plurality of light shielding areas LS. The transparent substrate 142 may include quartz. The plurality of light shielding patterns 144 may include chromium (Cr). The plurality of light transmitting areas LT may be defined by the plurality of light shielding patterns 144. According to some embodiments, to expose the first region 132 of the photoresist film 130 to light, a reflective photomask (not shown) for EUV exposure may be used instead of the photomask 140.

After the first region 132 of the photoresist film 130 is exposed to light according to process P230 of FIG. 1, the photoresist film 130 may undergo annealing. The annealing may be performed at a temperature of about 50° C. to about 400° C. for about 10 seconds to about 100 seconds, but embodiments of inventive concepts are not limited thereto.

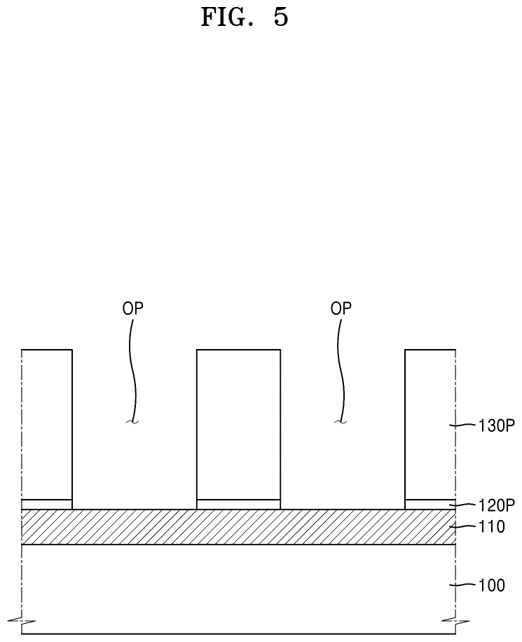

Referring to FIGS. 2 and 5, the first region 132 of the photoresist film 130 may be removed by developing the photoresist film 130 by using a developer. As a result, a photoresist pattern 130P including a second region 134 of the photoresist film 130, which has not been exposed to light, may be formed.

The photoresist pattern 130P may include a plurality of openings OP. After the photoresist pattern 130P is formed, a lower pattern 120P may be formed by removing portions of the lower film 120, which are exposed by the plurality of openings OP.

In some embodiments, an alkaline developer may be used to develop the photoresist film 130. The alkaline developer may include a 2.38 wt % tetramethylammonium hydroxide (TMAH) solution.

Because the photoresist pattern 130P is obtained from the photoresist composition including the photosensitive polymer that has a PDI of about 1.1 or less, a critical dimension of an intended processing region in the feature layer 110 may be precisely controlled when the feature layer 110 is processed by using the photoresist pattern 130P.

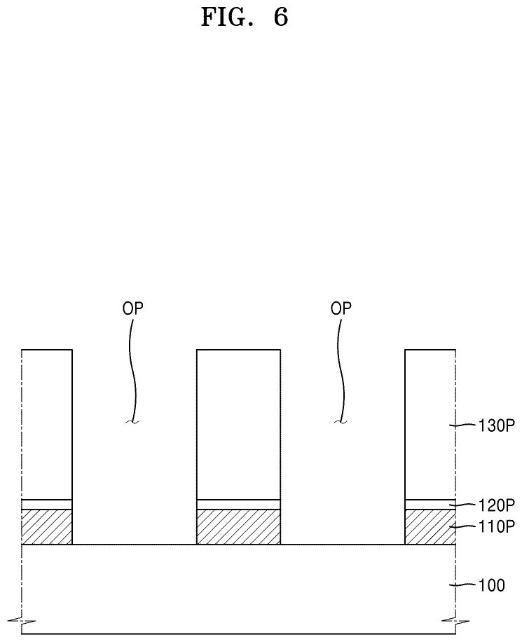

Referring to FIGS. 2 and 6, the feature layer 110 may be processed by using the photoresist pattern 130P (P250).

To process the feature layer 110, various processes, such as a process of etching the feature layer 110 exposed by an opening OP of the photoresist pattern 130P, a process of implanting impurity ions into the feature layer 110, a process of forming an additional film on the feature layer 110 through the opening OP, and a process of modifying a portion of the feature layer 110 through the opening OP, may be performed. FIG. 6 illustrates an example of forming a feature pattern 110P by etching the feature layer 110 exposed by the opening OP, as an example of a process of processing the feature layer 110.

In some embodiments, the process of forming the feature layer 110 may be omitted from the process described with reference to FIG. 3, and in this case, instead of process P250 described with reference to FIGS. 2 and 6, the substrate 100 may be processed by using the photoresist pattern 130P. For example, various processes, such as a process of etching a portion of the substrate 100 by using the photoresist pattern 130P, a process of implanting impurity ions into a portion of the substrate 100, a process of forming an additional film on the substrate 100 through the opening OP, and a process of modifying a portion of the substrate 100 through the opening OP, may be performed.

Because the photoresist pattern 130P is obtained from the photoresist composition including the photosensitive polymer that has a PDI of about 1.1 or less, the feature pattern 110P formed by using the photoresist pattern 130P may include a fine pattern having improved LWR and LER. For example, the feature pattern 110P may include a line-and-space pattern having a pitch of about 40 nm or less.

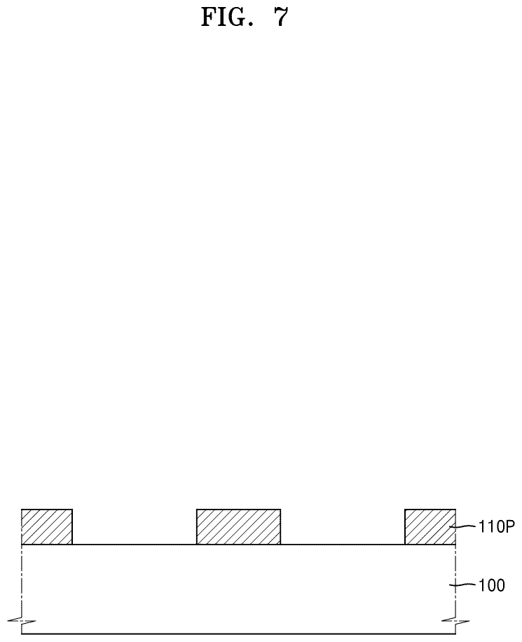

Referring to FIG. 7, in the resulting product of FIG. 6, the photoresist pattern 130P and the lower pattern 120P, which remain on the feature pattern 110P, may be removed. To remove the photoresist pattern 130P and the lower pattern 120P, ashing and strip processes may be used.

According to the method of manufacturing a semiconductor device, which has been described with reference to FIGS. 2 and 3 to 7, the LER and LWR of the photoresist pattern 130P obtained from the photoresist film 130, which is obtained from the photoresist composition according to some embodiments, may improve, thereby providing high pattern fidelity. Therefore, when a subsequent process is performed on the feature layer 110 and/or the substrate 100 by using the photoresist pattern 130P, critical dimensions of patterns or processing regions intended to be formed in the feature layer 110 and/or the substrate 100 may be precisely controlled, thereby improving the dimensional precision of the patterns or processing regions. In addition, the critical dimension (CD) distribution of patterns intended to be implemented on the substrate 100 may be uniformly controlled, and the productivity of a manufacturing process of a semiconductor device may improve.

While inventive concepts have been particularly shown and described with reference to embodiments thereof, it will be understood that various changes in form and details may be made therein without departing from the spirit and scope of the following claims.

What is claimed is:

1. A photosensitive polymer comprising:
repeating units represented by Formula 1, 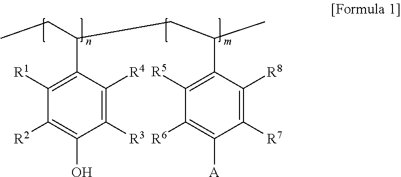
wherein, in Formula 1,
R¹, R², R³, R⁴, R⁵, R⁶, R⁷, and R⁸ are each independently a hydrogen atom, a C1-C3 linear or branched alkyl group, a substituted or unsubstituted C2-C3 linear or branched alkenyl group, a substituted or unsubstituted C2-C3 linear or branched alkynyl group, a substituted or unsubstituted C1-C3 alkoxy group, or a halogen element,
A is an acid-labile group having an acid desorption rate that is lower than an acid desorption rate of a trialkylsilyl group,
m and n are each an integer of 1 or more, and
the photosensitive polymer has a polydispersity index (PDI) of 1.1 or less.

2. The photosensitive polymer of claim 1, wherein the acid-labile group comprises a tertiary carbon atom.

3. The photosensitive polymer of claim 2, wherein the acid-labile group comprises an alkoxy group in which a tertiary carbon atom is directly bonded to an oxygen atom.

4. The photosensitive polymer of claim 3, wherein
the acid-labile group has one structure selected from a group having the following structures: 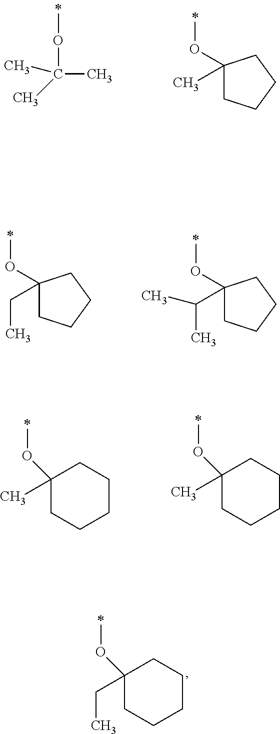
and
* represents a binding site.

5. The photosensitive polymer of claim 2, wherein
the acid-labile group comprises an ester group in which a tertiary carbon atom is directly bonded to an oxygen atom.

6. The photosensitive polymer of claim 5, wherein the acid-labile group has one structure selected from a group having the following structures: 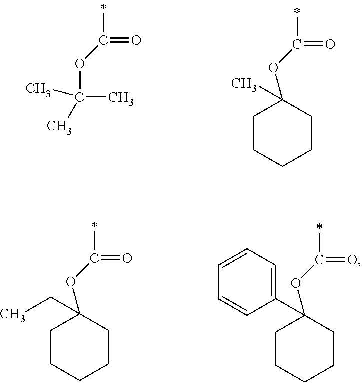
and
* represents a binding site.

7. A photoresist composition comprising:
a photoacid generator (PAG);
a solvent; and
a photosensitive polymer including repeating units that are represented by Formula 1, 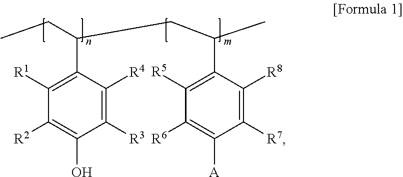
wherein, in Formula 1, R¹, R², R³, R⁴, R⁵, R⁶, R⁷, and R⁸ are each independently a hydrogen atom, a C1-C3 linear or branched alkyl group, a substituted or unsubstituted C2-C3 linear or branched alkenyl group, a substituted or unsubstituted C2-C3 linear or branched alkynyl group, a substituted or unsubstituted C1-C3 alkoxy group, or a halogen element,
A is an acid-labile group having an acid desorption rate that is lower than a acid desorption rate of a trialkylsilyl group.

8. The photoresist composition of claim 7, wherein the acid-labile group comprises an acid-labile group having a tertiary carbon atom.

9. The photoresist composition of claim 8, wherein the acid-labile group comprises an alkoxy group in which a tertiary carbon atom is directly bonded to an oxygen atom.

10. The photoresist composition of claim 9, wherein the acid-labile group has one structure selected from a group having the following structures: 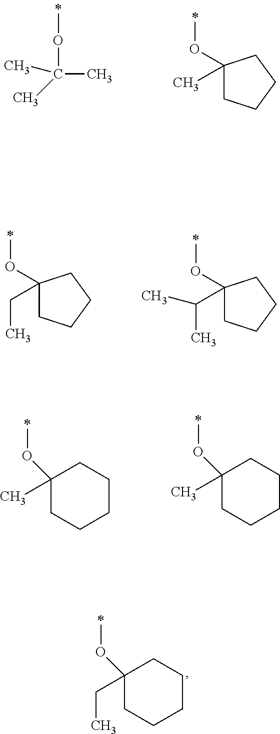
* represents a binding site.

11. The photoresist composition of claim 8, wherein the acid-labile group comprises an ester group in which a tertiary carbon atom is directly bonded to an oxygen atom.

12. The photoresist composition of claim 11, wherein the acid-labile group has one structure selected from a group having the following structures: 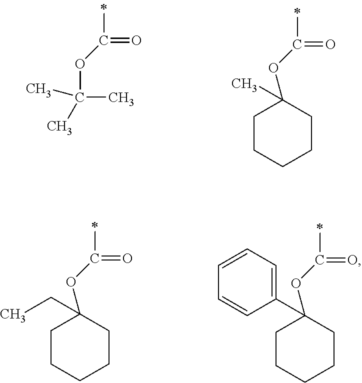
and
* represents a binding site.

13. A method of manufacturing a semiconductor device, the method comprising:
forming a photoresist film on a feature layer using a photoresist composition, a photoacid generator (PAG), and a solvent;
exposing a first region to light, the first region being a portion of the photoresist film, the exposing the first region to light forming an exposed region of the photoresist film and a non-exposed region of the photoresist film;
forming a photoresist pattern by removing the exposed region of the photoresist film using a developer; and
processing the feature layer by using the photoresist pattern, wherein
the photosensitive polymer has a polydispersity index (PDI) of 1.1 or less,
the photoresist composition includes a photosensitive polymer with repeating units represented by Formula 1 and obtained by anionic polymerization of a p-hydroxystyrene monomer and a p-styrene monomer, the p-hydroxystyrene monomer having a hydrogen atom of a hydroxyl group substituted with a trialkylsilyl group and the p-styrene monomer having a hydrogen atom substituted with an acid-labile functional group, 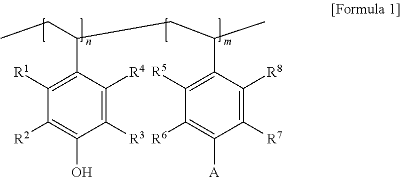
wherein, in Formula 1,
R¹, R², R³, R⁴, R⁵, R⁶, R⁷, and R⁸ are each independently a hydrogen atom, a C1-C3 linear or branched alkyl group, a substituted or unsubstituted C2-C3 linear or branched alkenyl group, a substituted or unsubstituted C2-C3 linear or branched alkynyl group, a substituted or unsubstituted C1-C3 alkoxy group, or a halogen element,
A is an acid-labile group having an acid desorption rate which is lower than that of a trialkylsilyl group, and
m and n are each an integer of 1 or more.

14. The method of claim 13, wherein the acid-labile group comprises an acid-labile group having a tertiary carbon atom.

15. The method of claim 14, wherein the acid-labile group comprises an alkoxy group in which a tertiary carbon atom is directly bonded to an oxygen atom.

16. The method of claim 15, wherein the acid-labile group has one structure selected from a group of the following structures: 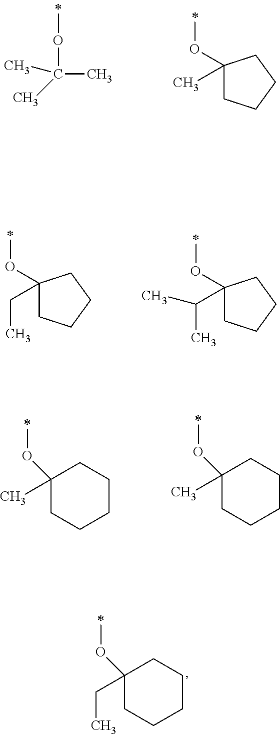
and
* represents a binding site.

17. The method of claim 14, wherein the acid-labile group comprises an ester group in which a tertiary carbon atom is directly bonded to an oxygen atom.

18. The method of claim 17, wherein the acid-labile group has one structure selected from a group of the following structures: 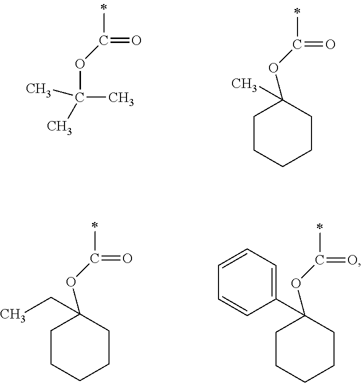
and
* represents a binding site.

19. The method of claim 13, wherein the exposing the first region of the photoresist film to light comprises irradiating the first region with an extreme ultraviolet (EUV) laser having a wavelength of 13.5 nm.

20. The method of claim 13, wherein
the processing the feature layer comprises forming a feature pattern corresponding to a line-and-space pattern, which has with a pitch of 40 nm or less.
